(19) United States
(12) Patent Application Publication
(10) Pub. No.: US 2024/0292539 A1
(43) Pub. Date: Aug. 29, 2024

(54) CIRCUIT BOARD INTERCONNECT INTERPOSER AND METHOD

(71) Applicant: Intel Corporation, Santa Clara, CA (US)

(72) Inventors: Juha Paavola, Hillsboro, OR (US); Justin M Huttula, Hillsboro, OR (US); Sami Heinisuo, Dallas, OR (US); Kari Mansukoski, Hillsboro, OR (US)

(21) Appl. No.: 18/113,414

(22) Filed: Feb. 23, 2023

(51) Int. Cl. H05K 1/14; H05K 3/36

(52) U.S. Cl. CPC H05K 1/141; H05K 3/368; H05K 2201/10378

(57) ABSTRACT

An electronic device and associated methods are disclosed. In one example, the electronic device includes a standoff interposer between an overlapping portion of a first circuit board and a second circuit board. In selected examples, electronic devices and methods described show one or more conductive pathways within a standoff interposer that provide electrical communication between circuit boards, such as data signals, power delivery, etc.

### TECHNICAL FIELD

Embodiments described herein generally relate to electrical interconnections and interconnect structures. Specific examples include electrical interconnections between circuit boards or other electrical distribution structures in devices that include semiconductor dies.

### BACKGROUND

Board-to-board connections consume printed circuit board (PCB) area in computer systems where two or more boards need to connect to each other. The space consumed by current interconnect solutions between boards requires either enlarging system board dimensions or leaving less space for the system components. Each connector is also a cost adder for an electronic system.

In selected configurations, a height difference between components creates a situation where boards need to be on a different Z-axis level. This makes a system either difficult to assemble and service, or more expensive due to added cost of existing connector solutions, or both.

It is desired to have electrical connectors and methods that address these concerns, and other technical challenges.

### BRIEF DESCRIPTION OF THE DRAWINGS

FIG. 1 shows an electronic device in accordance with some example embodiments.

FIG. 2 shows a cross section view of a standoff interposer in accordance with some example embodiments.

FIG. 3A shows an isometric view and limited cross section view of a standoff interposer in accordance with some example embodiments.

FIG. 3B shows an isometric view of a standoff interposer in accordance with some example embodiments.

FIG. 4 shows selected components of a device that includes a standoff interposer in accordance with some example embodiments.

FIG. 5 shows selected components of an electronic device in accordance with some example embodiments.

FIG. 6 shows a flow diagram of a method of manufacture of an electronic device in accordance with some example embodiments.

FIG. 7 shows a system that may incorporate a standoff interposer and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

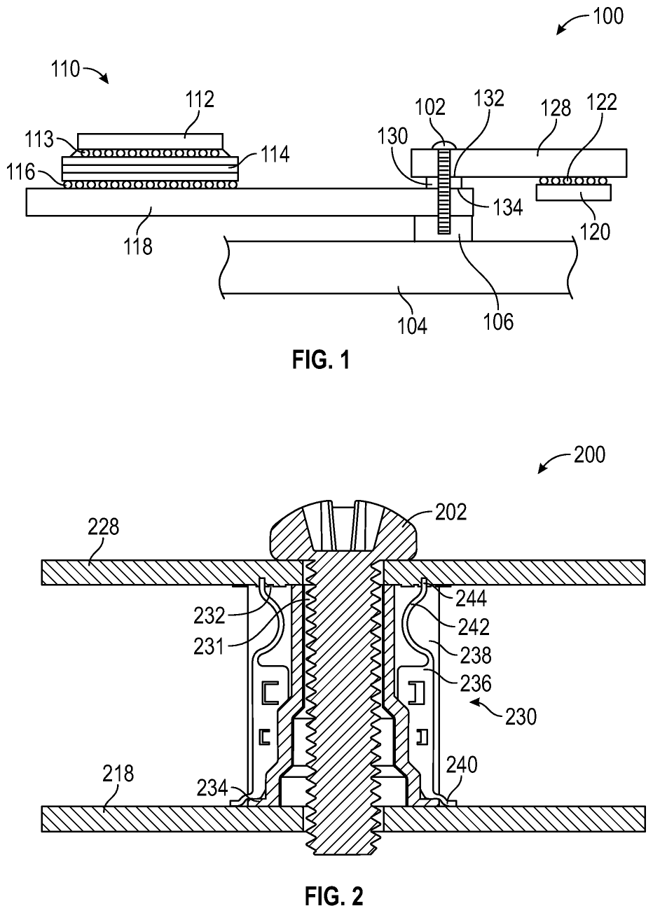

FIG. 1 shows an electronic device 100 according to one example. The electronic device 100 includes a first semiconductor device 110 coupled to a first circuit board 118. In the example shown, the first semiconductor device 110 includes a die 112 coupled to a package substrate 114. The die 112 is shown coupled to the package substrate 114 with first solder interconnects 113 and the package substrate 114 is further coupled to the first circuit board 118 with second solder interconnects 116. Although solder interconnects 113, 116 are shown, the invention is not so limited. Other examples of electrical interconnects include mechanical interconnects, such as sockets, other electrical connector materials apart from solder, etc.

FIG. 1 further shows a second circuit board 128 laterally overlapping a portion of the first circuit board 118. In the example of FIG. 1, the second circuit board 128 includes a second die 120 on the second circuit board 128. The second die 120 is shown coupled to the second circuit board 128 by third solder interconnects 122, although as noted above, the invention is not so limited. In one example, the die 112 on the first semiconductor device 110 is part of a system-on-chip (SOC) and the second die 120 is part of a graphics integrated circuit. These two specific electronic device types illustrate one example where height mismatches make use of a standoff interposer 130 advantageous.

FIG. 1 further shows a standoff interposer 130 located between the first circuit board 118 and the second circuit board 128 at the overlapping portion. A second circuit board connection surface 132 and a first circuit board connection surface 134 are shown making contact with a top and bottom of the standoff interposer 130. In one example, the standoff interposer includes one or more conductive pathways that provide an electrical connection between the first circuit board 118 and the second circuit board 128. A fastener 102 is also shown passing through a central passage of the standoff interposer 130. In FIG. 1, the fastener 102 is coupled to a chassis 104 of the electronic device 100. In the example shown, the fastener 102 includes a screw that is threaded into a portion 106 of the chassis 104, although the invention is not so limited. Other examples of fastener 102 include, but are not limited to, bayonet fasteners, friction fit pins, rivets, threaded studs and nuts, etc.

Electrical pathways are provided where conduction passes from a trace conductor on the first circuit board 118, through the standoff interposer 130 and through a trace conductor on the second circuit board 128. Although one or more semiconductor dies are shown on the circuit boards 118, 128, the invention is not so limited. Other examples of circuit board to circuit board conduction that do not involve dies are within the scope of the invention. Examples of conduction through traces and standoff interposers include, but are not limited to, data signals, power, ground, etc.

Although a central passage through the standoff interposer 130 is described, the invention is not so limited. A passage need not be central to the standoff interposer 130. In one example, the fastener 102 provides a compressive force on the standoff interposer 130 and enhances an electrical connection of one or more conductive pathways within the standoff interposer 130. Examples of an enhanced electrical connection includes, but is not limited to, compression of a spring interconnect.

In one example, the chassis 104 includes a device housing, such as an outer shell for a mobile phone, watch, GPS device etc. In one example, the chassis 104 includes an internal mounting frame in a computing device such as a desktop computer, a laptop computer, or server device, etc. In one example, connection to the chassis 104 is a direct connection. In one example, connection to the chassis 104 includes direct connection to a chassis that is integrally formed with an outer case. In one example, connection to the chassis 104 is indirect, and utilizes intermediate components to complete the physical connection.

FIG. 2 shows a cross section of a standoff interposer 230, similar to standoff interposer 130 from FIG. 1. A first circuit board 218 and a second circuit board 228 are shown, with the standoff interposer 230 coupled therebetween. A plurality of conductive pathways 236 are shown coupled between the first circuit board 218 and the second circuit board 228. In the example shown, the plurality of conductive pathways 236 are embedded in a body 238. In one example the body 238 includes a polymer. In one example, the polymer includes other dielectric materials for reinforcement, such as fibers or particles. Other dielectrics apart from polymers are also within the scope of the invention.

In the example of FIG. 2, a conductive pathway 236 includes a first end connection 240 and a second end connection 244. In one example, both the first end connection 240 and the second end connection 244 are the same type. In one example, the first end connection 240 and the second end connection 244 are different types. In the example of FIG. 2, the first end connection 240 includes a solderable pad. In the example of FIG. 2, the second end connection 244 includes a spring 242. In other examples, both ends include solderable pads, or both ends include springs. In a spring end example, the body 238 may include a slot to allow the spring 242 room to flex.

In one example of manufacture, a solderable pad end 240 of the standoff interposer 230 is soldered to the first circuit board 218 at a first circuit board connection surface 234 to make an electrical connection, and to hold the standoff interposer 230 in place. Then a fastener 202, such as a screw as illustrated in FIG. 2, is threaded through second circuit board 228 and a central passage 231 of the standoff interposer 230. When tightening the fastener 202, the spring 242 on the second end connection 244 compresses, and provides a force against a corresponding pad on a second circuit board connection surface 232.

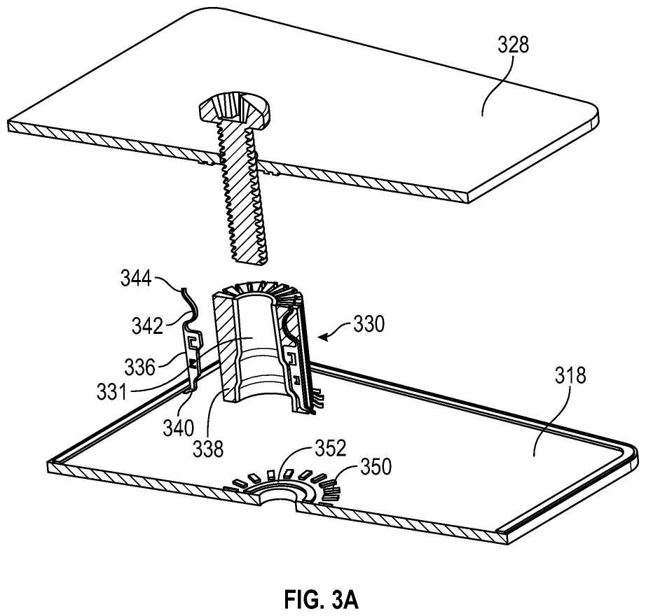

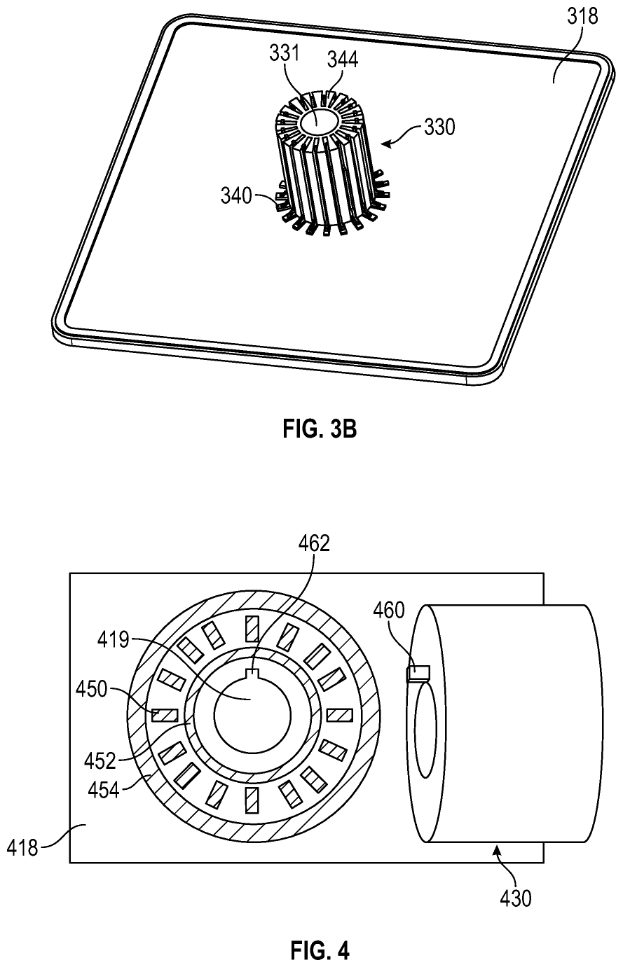

FIG. 3A shows a first circuit board 318 and a second circuit board 328 with a standoff interposer 330 similar to standoff interposers described in FIGS. 1 and 2. The standoff interposer 330 is shown in cross section, and an individual conductive pathway 336 is shown. Similar to the example of FIG. 2, the conductive pathway 336 includes a first end connection 340 and a second end connection 344. The first end connection 340 includes a solderable pad adapted for connection with a mating pad 350 on the first circuit board 318. The second end connection 344 includes a spring 342. In the example of FIG. 3A, the first circuit board 318 further includes a ground ring 352 adjacent to the mating pads 350. In one example, one or more ground connections adjacent to mating pads 350 provides a shielding effect that improves signal integrity in the mating pads 350. Although a ring is shown, other ground connections are also within the scope of the invention.

In one example, an inner and an outer ground ring are included adjacent to mating pads 350, as shown in FIG. 4. In one example, an inner surface of a central passage 331 is plated with a metal, or otherwise includes an inner conductor material that contacts the ground ring 352. An outer surface of the standoff interposer 330 can also be plated with a metal, or otherwise includes an outer conductor material that contacts an outer ground ring. In this way, the conductive pathways 336 can be shielded within both an inner and an outer surface.

FIG. 3B shows the standoff interposer 330 without the cross section view of FIG. 3A. The second end connections 344 are shown exposed at a top surface of the standoff interposer 330, and first end connections 340 are shown soldered or otherwise connected to the first circuit board 318. The central passage 331, which accommodates fastener 302 is further shown in FIG. 3A. In the example of FIGS. 3A and 3B, the standoff interposer 330 is shown in a cylindrical shape, although the invention is not so limited. Other shapes, such as oval shapes, square, or rectangular shapes, etc. are also within the scope of the invention.

In one example, a number of conductive pathways includes between 4 and 20 conductive pathways in a standoff interposer 330. In one example, a number of conductive pathways includes between 10 and 16 conductive pathways. Although multiple conductive pathways 336 are shown, and are arranged radially about a central axis, the invention is not so limited. A single conductive pathway is also within the scope of the invention, and arrangements for multiple conductive pathways other than radial are also within the scope of the invention. In one example, the conductive pathways include copper, although the invention is not so limited. Other conductor materials include other metals such as aluminum, steel, gold, silver, etc.

FIG. 4 shows a close up view of a portion of a standoff interposer 430 and a circuit board 418, similar to first circuit boards or second circuit boards discussed in other examples. Conductive pathways in the standoff interposer 430 are not shown in FIG. 4. Mating pads 350 are shown for coupling to first ends or second ends of conductive pathways as shown in other example Figures. An inner ground ring 452 and an outer ground ring 454 are shown adjacent to the mating pads 350. In one example, a first keying feature 460 is included to mate with a corresponding second keying feature 462. Although a peg and a notch are shown in the Figure, other geometries of keying features are within the scope of the invention, and may be included to aid in matching a desired conductive pathways with a desired mating pad on one or both circuit boards.

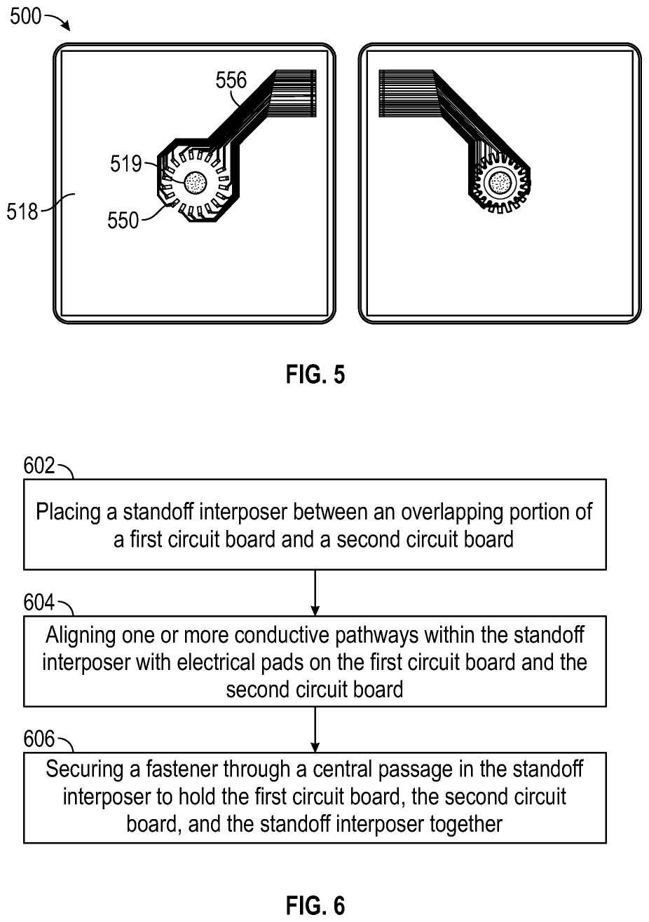

FIG. 5 shows conductive traces 556 that are connected to mating pads 550 of a circuit board 518. First ends or second ends of conductive pathways from standoff interposer examples are electrically connected to the mating pads 550 which in turn, distribute signals, power, etc. through the conductive traces 556 in the circuit board 518 to other components on the circuit board 518 (not shown). In this way, signals, power, etc. can be communicated between circuit boards by utilizing example standoff interposers as described. The standoff interposers provide a securing function that holds the circuit boards in place. The standoff interposers further provide a Z-height spacing function. The standoff interposers further provide an electrical connection function. Because of the multiple functions provided by examples of standoff interposers described, valuable circuit board real estate can be saved, in contrast to separate connectors such as flex circuit connectors that may require separate board real estate, and are more costly.

FIG. 6 shows a flow diagram of one example method of manufacture. In operation 602, a standoff interposer is placed between an overlapping portion of a first circuit board and a second circuit board. In operation 604, one or more conductive pathways are aligned within the standoff interposer with electrical pads on the first circuit board and the second circuit board. In operation 806, a fastener is secured through a central passage in the standoff interposer to hold the first circuit board, the second circuit board, and the standoff interposer together.

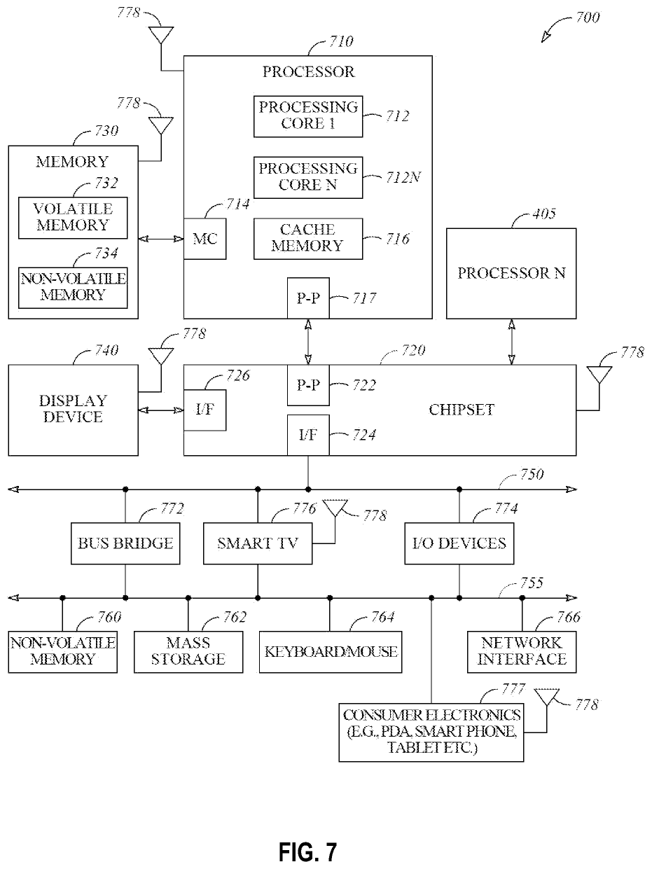

FIG. 7 illustrates a system level diagram, depicting an example of an electronic device (e.g., system) that may include a standoff interposer and/or methods described above. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 includes a system on a chip (SOC) system.

In one embodiment, processor 710 has one or more processor cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals. In one example, any combination of components in a chipset may be separated by a continuous flexible shield as described in the present disclosure.

Chipset 720 connects to display device 740 via interface 726. Display 740 may be, for example, a liquid crystal display (LCD), a light emitting diode (LED) array, an organic light emitting diode (OLED) array, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

To better illustrate the method and apparatuses disclosed herein, a non-limiting list of embodiments is provided here:

Example 1 includes an electronic device. The electronic device includes a semiconductor die coupled to a first circuit board, and a second circuit board laterally overlapping a portion of the first circuit board. The electronic device includes a standoff interposer having a central passage, the standoff interposer located between the first circuit board and the second circuit board at the overlapping portion, the standoff interposer including one or more conductive pathways coupled between the first circuit board and the second circuit board, and a fastener passing through the central passage.

Example 2 includes the electronic device of example 1, further including a semiconductor die coupled to the first circuit board.

Example 3 includes the electronic device of any one of examples 1-2, wherein the standoff interposer is cylindrical.

Example 4 includes the electronic device of any one of examples 1-3, wherein the conductive pathways are arranged radially about the central passage.

Example 5 includes the electronic device of any one of examples 1-4, further including a ground ring on at least one side of the conductive pathways.

Example 6 includes the electronic device of any one of examples 1-5, further including an inner and outer ground ring adjacent to the conductive pathways.

Example 7 includes the electronic device of any one of examples 1-6, wherein at least one of the conductive pathways includes a spring at an end of the conductive pathway.

Example 8 includes the electronic device of any one of examples 1-7, wherein at least one of the conductive pathways includes solder at an end of the conductive pathway.

Example 9 includes the electronic device of any one of examples 1-8, wherein the fastener includes a screw.

Example 10 includes the electronic device of any one of examples 1-9, wherein the standoff interposer includes a polymer body and wherein the conductive pathways include copper.

Example 11 includes an electronic device. The electronic device includes a semiconductor die coupled to a first circuit board, and a second circuit board laterally overlapping a portion of the first circuit board. The electronic device also includes a standoff interposer having a central passage, the standoff interposer located between the first circuit board and the second circuit board at the overlapping portion, the standoff interposer including one or more conductive pathways coupled between the first circuit board and the second circuit board, and a fastener passing through the central passage, the fastener coupled to a chassis of the electronic device.

Example 12 includes the electronic example 11, wherein the chassis is integral with an outer case of the electronic device.

Example 13 includes the electronic device of any one of examples 11-12, further including an antenna in communication with the semiconductor die.

Example 14 includes the electronic device of any one of examples 11-13, further including a second die on the second circuit board.

Example 15 includes the electronic device of any one of examples 11-14, wherein the first circuit board includes a system on chip and wherein the second circuit board includes a graphics integrated circuit.

Example 16 include a method of forming an electronic device. The method includes placing a standoff interposer between an overlapping portion of a first circuit board and a second circuit board, aligning one or more conductive pathways within the standoff interposer with electrical pads on the first circuit board and the second circuit board, and securing a fastener through a central passage in the standoff interposer to hold the first circuit board, the second circuit board, and the standoff interposer together.

Example 17 includes the method of example 16, wherein securing the fastener includes compressing a spring on an end of at least one of the conductive pathways.

Example 18 includes the method of any one of examples 16-17, further including soldering at an interface of at least one of the conductive pathways.

Example 19 includes the method of any one of examples 16-18, wherein securing the fastener includes threading a screw.

Example 20 includes the method of any one of examples 16-19, further including injection molding a body around the one or more conductive pathways to form the standoff interposer.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device, comprising:
a first circuit board;
a second circuit board laterally overlapping a portion of the first circuit board;
a standoff interposer having a central passage, the standoff interposer located between the first circuit board and the second circuit board at the overlapping portion, the standoff interposer including one or more conductive pathways coupled between the first circuit board and the second circuit board; and
a fastener passing through the central passage.

2. The electronic device of claim 1, further including a semiconductor die coupled to the first circuit board.

3. The electronic device of claim 1, wherein the standoff interposer is cylindrical.

4. The electronic device of claim 1, wherein the conductive pathways are arranged radially about the central passage.

5. The electronic device of claim 1, further including a ground ring on at least one side of the conductive pathways.

6. The electronic device of claim 1, further including an inner and outer ground ring adjacent to the conductive pathways.

7. The electronic device of claim 1, wherein at least one of the conductive pathways includes a spring at an end of the conductive pathway.

8. The electronic device of claim 1, wherein at least one of the conductive pathways includes solder at an end of the conductive pathway.

9. The electronic device of claim 1, wherein the fastener includes a screw.

10. The electronic device of claim 1, wherein the standoff interposer includes a polymer body and wherein the conductive pathways include copper.

11. An electronic device, comprising:
a semiconductor die coupled to a first circuit board;
a second circuit board laterally overlapping a portion of the first circuit board;
a standoff interposer having a central passage, the standoff interposer located between the first circuit board and the second circuit board at the overlapping portion, the standoff interposer including one or more conductive pathways coupled between the first circuit board and the second circuit board; and
a fastener passing through the central passage, the fastener coupled to a chassis of the electronic device.

12. The electronic device of claim 11, wherein the chassis is integral with an outer case of the electronic device.

13. The electronic device of claim 11, further including an antenna in communication with the semiconductor die.

14. The electronic device of claim 11, further including a second die on the second circuit board.

15. The electronic device of claim 11, wherein the first circuit board includes a system on chip and wherein the second circuit board includes a graphics integrated circuit.

16. A method of forming an electronic device, comprising:
placing a standoff interposer between an overlapping portion of a first circuit board and a second circuit board;
aligning one or more conductive pathways within the standoff interposer with electrical pads on the first circuit board and the second circuit board; and
securing a fastener through a central passage in the standoff interposer to hold the first circuit board, the second circuit board, and the standoff interposer together.

17. The method of claim 16, wherein securing the fastener includes compressing a spring on an end of at least one of the conductive pathways.

18. The method of claim 16, further including soldering at an interface of at least one of the conductive pathways.

19. The method of claim 16, wherein securing the fastener includes threading a screw.

20. The method of claim 16, further including injection molding a body around the one or more conductive pathways to form the standoff interposer.
